(19) United States
(12) Patent Application Publication
(10) Pub. No.: US 2007/0271750 A1
(43) Pub. Date: Nov. 29, 2007

(54) METHOD FOR MANUFACTURING PIEZOELECTRIC LAYERS

(75) Inventors: Mayumi HAMADA, Suwa (JP); Takeshi KIJIMA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/753,625

(22) Filed: May 25, 2007

(30) Foreign Application Priority Data
May 26, 2006 (JP) 2006-146457

(51) Int. Cl. H01L 21/00; H01L 21/64; H01L 21/44

(52) U.S. Cl. 29/25.01; 438/678

(57) ABSTRACT

A method for manufacturing a piezoelectric layer includes the steps of: forming a material layer of a piezoelectric layer composed of potassium sodium niobate above a base substrate; introducing material gas containing water vapor and oxygen gas in an oxidizing gas forming section; and heating the material gas in the oxidizing gas forming section and supplying the material gas in an oxidation furnace to thereby oxidize the material layer.

The entire disclosure of Japanese Patent Application No. 2006-146457, filed May 26, 2006 is expressly incorporated by reference herein.

### BACKGROUND

1. Technical Field

The present invention relates to a method for manufacturing a piezoelectric layer composed of potassium sodium niobate.

2. Related Art

A demand for surface acoustic wave devices has rapidly increased along with a remarkable development in the communication field centered at mobile communication equipment such as cellular phones. The development of the surface acoustic wave device is trending toward a reduction in size and an increase in efficiency and frequency. This requires a higher electromechanical coupling coefficient (k²), more stable temperature properties, and a higher surface acoustic wave propagation velocity.

A surface acoustic wave device having a structure in which interdigital transducers are formed on a piezoelectric single crystal has mainly been used. As typical examples of the piezoelectric single crystal, quartz, lithium niobate (LiNbO₃), and lithium tantalum (LiTaO₃) may be listed. In the case of an RF filter for which an increase in band and a decrease in loss in the passband are required, LiNbO₃ having a large electromechanical coupling coefficient is used. On the other hand, in the case of an IF filter that needs a stable temperature property even with a narrow band, quartz having a small center frequency temperature coefficient is used. Furthermore, LiTaO₃ having an electromechanical coupling coefficient and a center frequency temperature coefficient each in between those of LiNbO₃ and quartz plays an intermediate role between the two. Also, recently, a cut angle that exhibits a large value of electromechanical coupling coefficient in potassium niobate (KNbO₃) single crystal has been found. A KNbO₃ single crystal plate is described in Japanese Laid-open patent application, JP-A-10-65488.

In a surface acoustic wave device using a piezoelectric single crystal substrate, properties such as the electromechanical coupling factor, temperature coefficient, and speed of sound are values specific to the material and are determined by the cut angle and the propagation direction. For example, a 0° Y-X KNbO₃ single crystal substrate has an excellent electromechanical coupling coefficient, but does not exhibit a zero-temperature characteristic around room temperature, like the 45° to 75° rotated Y-X KNbO₃ single crystal substrate.

### SUMMARY

In accordance with an aspect of the present invention, a method for manufacturing a piezoelectric layer composed of potassium sodium niobate is provided.

A method for manufacturing a piezoelectric layer in accordance with an embodiment of the invention includes the steps of: forming a material layer of a piezoelectric layer composed of potassium sodium niobate above a base substrate; introducing material gas containing water vapor and oxygen gas in an oxidizing gas forming section; and heating the material gas in the oxidizing gas forming section and supplying the material gas in an oxidation furnace to thereby oxidize the material layer.

According to the method for manufacturing a piezoelectric layer described above, a piezoelectric layer composed of potassium sodium niobate can be formed at a lower temperature, compared to an ordinary method for manufacturing a piezoelectric layer. Details of the method are described below.

It is noted that, in descriptions concerning the invention, the term “above” may be used, for example, in a manner as “a specific member (hereafter referred to as ‘B’) formed ‘above’ another specific member (hereafter referred to as ‘A’).” In descriptions concerning the invention, the term “above” is used, in such an exemplary case described above, assuming that the use of the term includes a case in which “B” is laminated directly on “A,” and a case in which “B” is laminated over “A” through another member.”

In the method for manufacturing a piezoelectric layer in accordance with an aspect of the present embodiment, the step of forming the material layer may include coating a solution containing a raw material solution for the piezoelectric layer, and applying a heat treatment to the solution coated.

In the method for manufacturing a piezoelectric layer in accordance with an aspect of the present embodiment, the oxidizing gas forming section may at least include a first gas chamber section, a plurality of conduction pipes connected to the first gas chamber section, a second gas chamber section connected to the plurality of conduction pipes, and a supply section connected to the second gas chamber for supplying the oxidizing gas in the oxidation furnace.

In the method for manufacturing a piezoelectric layer in accordance with an aspect of the present embodiment, the step of supplying the oxidizing gas from the oxidizing gas forming section to the oxidation furnace may include a first step of supplying the oxidizing gas to the first gas chamber section, and a second step of supplying the oxidizing gas through the plurality of conduction pipes to the second gas chamber section.

In the method for manufacturing a piezoelectric layer in accordance with an aspect of the present embodiment, the temperature of the base substrate in the step of oxidizing the material layer may be between 200° C. and 500° C.

In the method for manufacturing a piezoelectric layer in accordance with an aspect of the present embodiment, the temperature of the base substrate in the step of oxidizing the material layer may be between 200° C. and 300° C.

In the method for manufacturing a piezoelectric layer in accordance with an aspect of the present embodiment, water molecules of the oxidizing gas that is supplied to the oxidation furnace may be in a non-cluster state.

### BRIEF DESCRIPTION OF THE DRAWINGS

FIG. 1 is a cross-sectional view schematically showing a step of manufacturing a laminate having a piezoelectric layer in accordance with an embodiment of the invention.

FIG. 2 is a schematic diagram of a piezoelectric layer forming apparatus in accordance with an embodiment of the invention.

FIG. 3 is a cross-sectional view schematically showing a step of manufacturing a laminate having a piezoelectric layer in accordance with the embodiment of the invention.

FIG. 4 is a perspective view schematically showing the main portion of a piezoelectric layer forming apparatus.

FIG. 5 a perspective view schematically showing a modified example of the main portion of the piezoelectric layer forming apparatus.

FIG. 6 is a cross-sectional view schematically showing a step of manufacturing a laminate having a piezoelectric layer in accordance with the embodiment of the invention.

FIG. 7 is a cross-sectional view schematically showing an example of a laminate having a piezoelectric layer in accordance with an embodiment of the invention.

FIG. 8 is a cross-sectional view schematically showing an example of a laminate having a piezoelectric layer in accordance with an embodiment of the invention.

FIG. 9 is a graph of XRD in the embodiment example.

FIG. 10 is a graph showing a ¹H-NMR analysis result of water obtained by passing a material gas through an oxidizing gas forming section.

FIG. 11 is a graph showing a ¹H-NMR analysis result of purified water.

FIG. 12 is a graph showing ¹H-NMR analysis results of water obtained by passing material gas through an oxidizing gas forming section and purified water, respectively.

### DESCRIPTION OF EXEMPLARY EMBODIMENTS

Preferred embodiments of the present invention are described below with reference to the accompanying drawings.

### 1. Method for Manufacturing Piezoelectric Layer

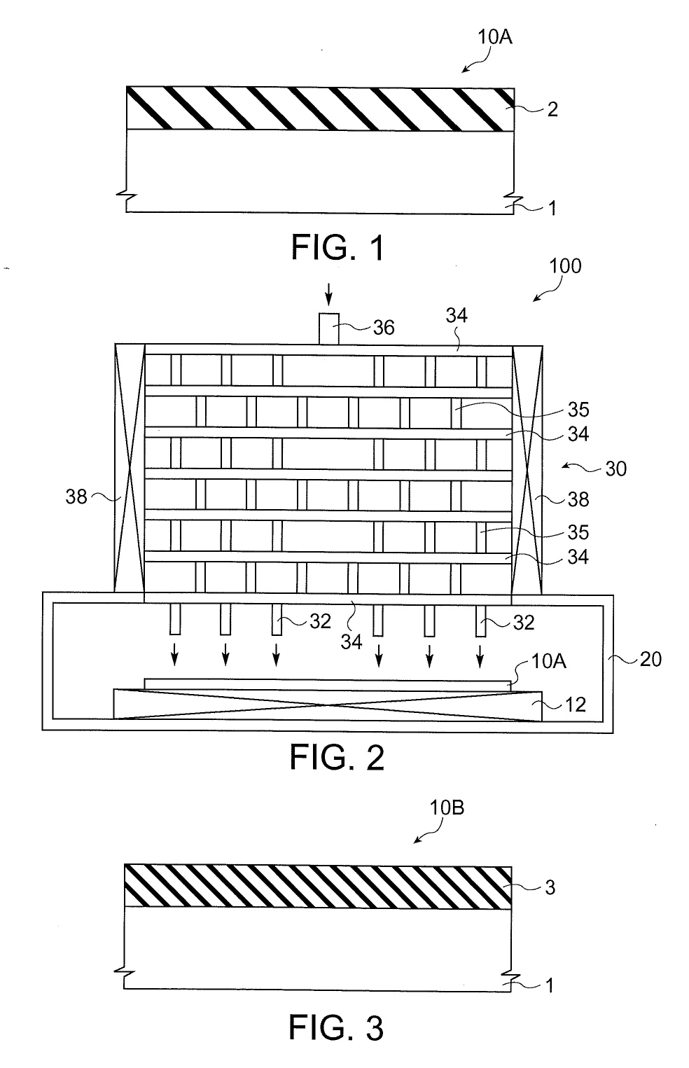

FIG. 1, FIG. 3 and FIG. 6 are cross-sectional views schematically showing an example of a manufacturing method for manufacturing a laminate 10 having a piezoelectric layer composed of potassium sodium niobate in accordance with an embodiment of the invention. FIG. 2 is a schematic diagram of an apparatus 100 for forming a piezoelectric layer.

The laminate 10 having a piezoelectric layer composed of potassium sodium niobate in accordance with the present embodiment may be formed, for example, in a manner described below.

(A) First, a base substrate 1 is prepared. The base substrate 1 is selected according to the usage of a piezoelectric layer 3, and its material and composition are not particularly limited. As the base substrate 1, for example, a dielectric substrate and a semiconductor substrate can be used. As a dielectric substrate, for example, a sapphire substrate, a STO (SrTiO₃) substrate, a Nb:STO (Nb doped SrTiO₃) substrate, a plastic substrate, a glass substrate, or the like may be used. As a semiconductor substrate, for example, a silicon substrate may be used. Also, the base substrate 1 may be a single substrate or a laminate composed of a substrate and a layer laminated on the substrate.

(B) Next, as shown in FIG. 1, a material layer 2 for forming a piezoelectric layer 3 (see FIG. 3) composed of potassium sodium niobate is formed on the base substrate 1. The material layer 2 may be formed by a sol-gel method, a MOD (Metal Organic Decomposition) method or the like.

Concretely, a solution is prepared by mixing plural raw material solutions such that the piezoelectric layer 3 has a desired composition ratio. Then, the solution is coated on the base substrate 1 by a spin coat method or a dipping method (mixed solution coating step).

The raw material solution (a precursor solution) for forming the material layer 2 may be made through mixing organometallic compounds each containing a constituent metal of the piezoelectric material composing the piezoelectric layer 3 such that each of the constituent metals has a desired mole ratio, and dissolving or dispersing the mixture in an organic solvent such as alcohol (for example, n-buthanol). As the organometallic compounds that contain constituent metals of the piezoelectric material, for example, metal alkoxides, organic acid salts, and β diketone complexes can be used. Concretely, the following piezoelectric materials may be used.

As an organometallic compound containing sodium (Na), for example, a sodium ethoxide may be enumerated. As an organometallic compound containing potassium (K), for example, a potassium ethoxide may be enumerated. As an organometallic compound containing niobium (Nb), for example, a niobate ethoxide may be enumerated. It is noted that the organometallic compounds containing the constituent metals of the piezoelectric material are not limited to the above, and known materials may also be used.

A variety of additives, such as, stabilizer agent and the like may be added in the raw material solution if necessary. When hydrolysis and polycondensation are to be caused in the precursor solution, an appropriate amount of water together with acid or base as a catalyst may be added in the precursor solution.

Next, a heat treatment is conducted in an air atmosphere using a hot plate or the like, for example, at a temperature that is about 10° C. higher than the boiling temperature of the solvent used in the raw material solution (for example, at 150° C.) (drying thermal treatment step).

Next, in order to decompose and remove ligands of the organometallic compounds used in the raw material solution, a heat treatment is conducted in an air atmosphere using a hot plate or the like, for example, at temperatures of about 300° C.-400° C. (degreasing thermal treatment step).

A series of steps consisting of the mixed solution coating step, the drying thermal treatment step, and the degreasing thermal treatment step may be repeated a desired number of times depending on the desired film thickness.

By the steps described above, a laminate 10A in which the material layer 2 is formed on the base substrate 1 is obtained, as shown in FIG. 1.

(C) Next, a piezoelectric layer 3 is formed with a piezoelectric layer forming apparatus 100, as shown in FIG. 2 and FIG. 3. The piezoelectric layer forming apparatus 100 in accordance with an embodiment of the invention is described below.

The piezoelectric layer forming apparatus 100 includes an oxidation surface 20, a base substrate mounting section 12, and an oxidizing gas forming section 30.

The base substrate mounting section 12 is provided within the oxidation furnace 20. The base substrate 1 with the material layer 2 (the laminate 10A) laminated thereon by the steps described above can be mounted on the base substrate mounting section 12. The base substrate mounting section 12 may be equipped with a heater. The laminate 10A can be heated by the heater.

The oxidizing gas forming section 30 is provided above the base substrate mounting section 12. The oxidizing gas forming section 30 includes a supply section 32, a plurality of gas chamber sections 34, a plurality of conduction pipes 35, an introduction section 36, and a heater section 38. Active oxidizing gas is ejected (supplied) through the supply section 32 toward the base substrate mounting section 12. The active oxidizing gas may include, for example, active oxygen gas. The supply section 32 can be formed from, for example, elongated cylindrical pipes. It is noted that, in the illustrated example, the elongated cylindrical pipe of the supply section 32 is in a tubular shape. However, for example, opening sections may be provided in the lower surface of the gas chamber section 34 at the lowermost stage, and the opening sections can be used as the supply section 32.

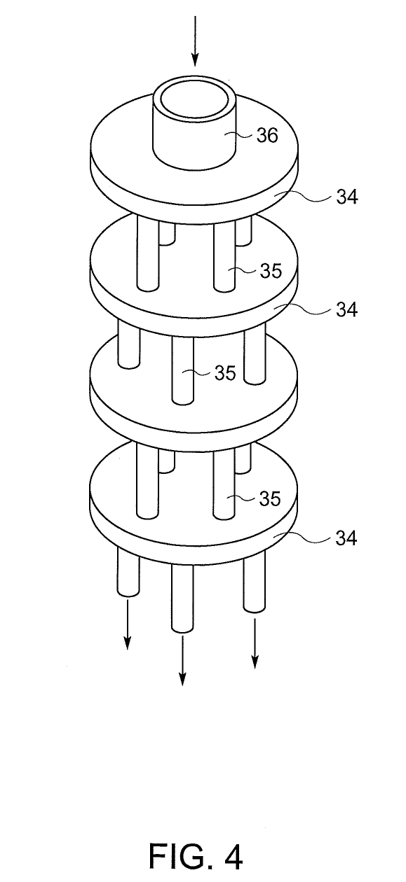

The plural gas chamber sections 34 are spaced a gap from one another and disposed above the supply section 32. In the example shown in FIG. 2, the gas chamber sections 34 are formed in seven stages. However, the number of stages is not particularly limited, and can be increased or reduced depending on the requirement. The plural conduction pipes 35 connect the plural gas chamber sections 34 with one another. The number of the conduction pipes 35 to be disposed at each stage is not particularly limited, and can be increased or reduced depending on the requirement. As shown in FIG. 4, adjacent ones of the plural conduction pipes 35 in a vertical direction in the figure may be arranged at positions shifted from one another as viewed in a plan view. In the illustrated example, as viewed in a plan view, the conduction pipes 35 are arranged at positions shifted through 45 degrees about the center of the gas chamber section 34. It is noted that FIG. 4 is a perspective view schematically showing the main portion of the piezoelectric layer manufacturing apparatus 100, and its illustration including the number of members and their sizes is simplified for the sake of convenience. Each of the gas chamber sections 34 may be formed from, for example, a flat cylindrical pipe, as shown in the figure. Further, each of the conduction pipes 35 may be formed from, for example, an elongated cylindrical pipe, as shown in the figure. The diameter of the gas chamber section 34 in a plan view is greater than the diameter of the conduction pipe 35 in a plan view, as shown in the figure. It is noted that the shape and size of the gas chamber section 34 and the conduction pipe 35 are not limited to the example shown in the figure, and can be changed according to the requirement.

Raw material gas containing water vapor and oxygen gas is introduced through the introduction section 36. The introduction section 36 may be formed from, for example, a cylindrical pipe. The heater section 38 is capable of heating the plural gas chamber sections 34 and the plural conduction pipes 35.

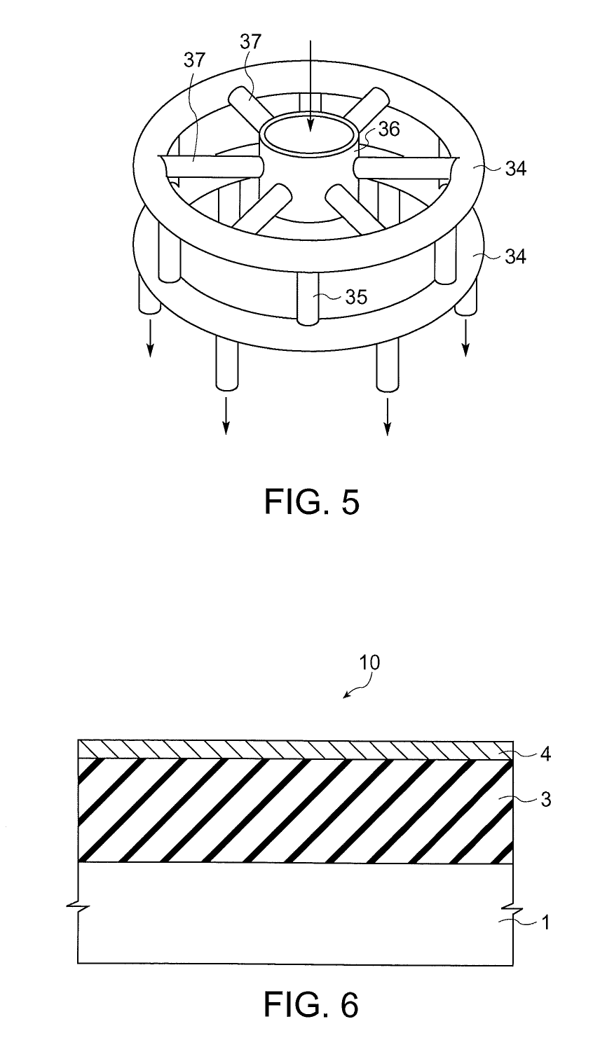

The gas chamber sections 34 and the conduction pipes 35 may be made in a configuration and an arrangement, for example, as shown in FIG. 5. FIG. 5 is a perspective view schematically showing a modified example of the main portion of the piezoelectric layer manufacturing apparatus 100, and its illustration including the number of members and their sizes is simplified for the sake of convenience. The gas chamber section 34 may be formed from an annular pipe, for example, as shown in the figure. The outside diameter of the gas chamber section 34 in a plan view is greater than the diameter of the conduction pipe 35 in a plan view, as shown in the figure. In the illustrated example, as viewed in a plan view, adjacent ones of the plural conduction pipes 35 arranged in a vertical direction in the figure are disposed at positions shifted through 45 degrees about the center of the gas chamber section 34. The gas chamber section 34 at the topmost stage is connected to the introduction section 36 by a plurality of (six, in the illustrated example) connection pipes 37. The introduction section 36 may be formed from a circular pipe with its bottom side being closed, for example, as shown in the figure. The connection pipes 37 are radially arranged about the conduction section 36 as the center, as viewed in a plan view. It is noted that the modified example is an example, and the invention is not limited to the modified example.

A piezoelectric layer 3 is formed by the piezoelectric layer apparatus 100 described above. Concretely, first, as shown in FIG. 2, a laminate 10 in which a material layer 2 is laminated on a base substrate 1 is set at the base substrate mounting section 12. Then, raw material gas containing water vapor (H₂O) and oxygen gas (O₂) is introduced in the oxidizing gas forming section 30. The raw material gas is first introduced into the introduction section 36. The gas within the introduction section 36 is supplied to the gas chamber section 34 disposed at the topmost stage. At this time, the gas discharged from the introduction section 36 is supplied through the plural conduction pipes 35 connected to the gas chamber section 34 at the topmost stage to the gas chamber section 34 disposed in the next lower stage. At this time also, the gas discharged from the multiple conduction pipes 35 is collided with the bottom surface of the gas chamber section 34 and diffused. In this manner, the gas introduced through the introduction section 36 repeats collisions with the bottom surface of each of the gas chamber sections 34 and flows from the gas chamber section 34 at the topmost stage to the gas chamber section 34 at the lowermost stage.

In other words, first, the gas is supplied to the gas chamber section (first gas chamber section) 34 disposed at the top stage (first step). Then, the gas is supplied through the plural conduction pipes 35 connected to the first gas chamber section 34 to the gas chamber section (second gas chamber section) 34 disposed at a lower stage (second step). Then, a series of steps from the first step to the second step is repeated from the gas chamber section 34 at the topmost stage to the gas chamber section 34 at the lowermost stage, whereby the gas can flow while repeating collisions.

The gas chamber sections 34 and the conduction pipes 35 are heated by the heater section 38, and the gas flowing inside thereof is also heated. The gas that has flowed from the gas chamber section 34 at the topmost stage to the gas chamber section 34 at the lowermost stage is discharged (supplied) into the oxidation furnace 20 through the supply section 32 as active oxidizing gas. Within the oxidation furnace 20, the laminate 10A is heated by the base substrate mounting section 12. In this manner, a heat treatment can be applied to the material layer 2 in the active oxidizing gas atmosphere. By this heat treatment, the material layer 2 is oxidized and crystallized, whereby a laminate 10B having the base substrate 1 and the piezoelectric layer 3 formed thereon can be obtained, as shown in FIG. 3. The temperature of the base substrate 1 in the heat treatment step may be, for example, between 200° C. and 500° C., or between 200° C. and 300° C.

The piezoelectric layer 3 formed in this manner is composed of piezoelectric material that is expressed by a composition formula, (KₐNa₁₋ₐ)ₓNbO₃. In the composition formula, “a” may preferably be in the range of 0.1<a<1, and more preferably be in the range of 0.2≦a≦0.7, and “x” may preferably be in the range of 1≦x≦1.2, and more preferably be in the range of 1<x≦1.1. The piezoelectric material expressed by the composition formula, (KₐNa₁₋ₐ)ₓNbO₃, has an orthorhombic structure at room temperature. In the composition formula above, when the value “a” is in the range described above, the phase changing temperature at which the phase changes from orthorhombic to rhombohedral (a≦0.55), and from orthorhombic to monoclinic (0.55≦a) becomes below −40° C., which is favorable because stable characteristics can be obtained in a low temperature region. When the value “a” is less than 0.1, heterogeneous phases are generated due to vaporization of potassium at the time of the heat treatment for crystallization, which causes negative influences on the properties such as piezoelectric characteristics and ferroelectric characteristics. The value “x” may preferably be in the range described above, because vaporization of potassium is suppressed as crystals are formed at low temperatures, and thus the density of the layer improves.

Also, preferably, the piezoelectric layer 3 composed of potassium sodium niobate obtained in accordance with the present embodiment may be preferentially oriented in pseudo cubic (100). A typical layer thickness of the piezoelectric layer 3 may be selected depending on the usage of the piezoelectric layer 10. The typical layer thickness of the piezoelectric layer 3 ranges from 300 nm to 3.0 μm. However, the upper limit value of the thickness may be increased, as long as the density of the layer as a thin layer can be maintained, and the crystal orientation can be maintained, and the thickness up to about 10 μm may be permissible.

(D) Next, as shown in FIG. 6, depending on the necessity, an upper electrode 4 is formed on the piezoelectric layer 3. As the upper electrode 4, for example, a layer of platinum (Pt), or a film having a layer of conductive oxide in a perovskite structure (for example, LaNiO₃, SrRuO₃ or the like) and a layer of platinum laminated thereon may be used, without any particular limitation. The upper electrode 4 may be formed by, for example, a sputter method, a spin coat method, a chemical vapor phase deposition (CVD) method, or a laser ablation method.

(E) Next, post annealing can be conducted in an oxygen atmosphere depending on the necessity by using RTA (rapid thermal annealing) or the like. By this, a good interface between the upper electrode 4 and the piezoelectric layer 3 can be formed, and the crystallinity of the piezoelectric layer 3 can be improved.

By the steps described above, the laminate 10 having the piezoelectric layer 3 composed of potassium sodium niobate in accordance with the present embodiment.

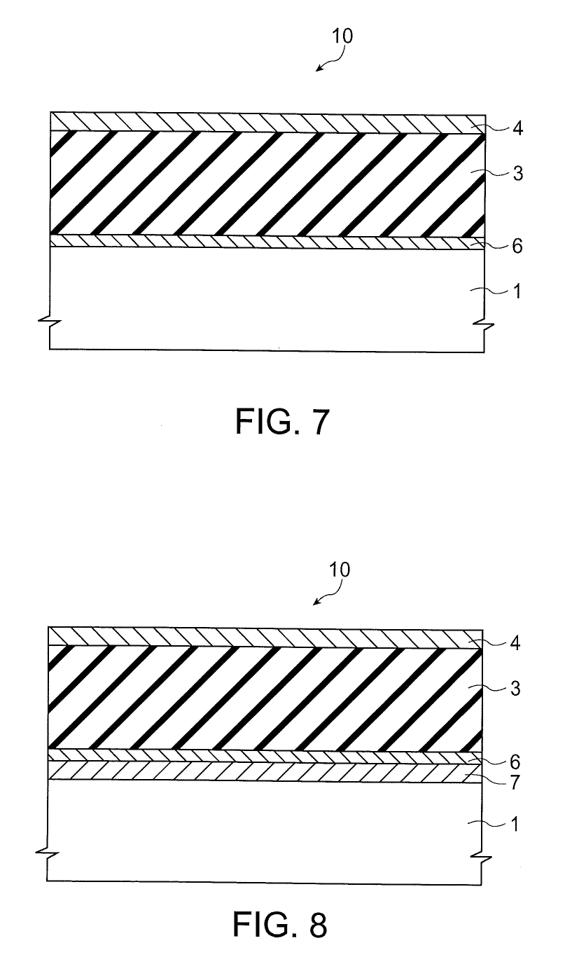

The laminate 10 is not limited to the one shown in FIG. 6, and can be modified in a variety of modes depending on the usage. The laminate 10 may have an orientation control layer 6 on the base substrate 1, for example, as shown in FIG. 7. In this case, after the step (A) described above, the orientation control layer 6 is formed on the base substrate 1.

The orientation control layer 6 is called a buffer layer or a seed layer, and has a function to control the crystal orientation of the piezoelectric layer 3. In other words, the piezoelectric layer 3 formed on the orientation control layer 6 has a crystal structure that succeeds the crystal structure of the orientation control layer 6. As the material of the orientation control layer 6, a compound oxide having a crystal structure similar to that of the piezoelectric layer 3 can be used. As the orientation control layer 6, perovskite oxides, such as, for example, nickel lanthanate (LaNiO₃) may be used. Nickel lanthanate may be polycrystal. The orientation control layer 6 may only need to control the orientation of the piezoelectric layer 3, and may have a film thickness of, for example, about 50 nm to 100 nm. When nickel lanthanate is used as the orientation control layer 6, a sputter method may be used. By forming the orientation control layer 6, the piezoelectric layer 3 can have better crystallinity and orientation, reflecting the crystal structure of the orientation control layer 6.

Also, as shown in FIG. 8, the laminate 10 may include a base substrate 1, a lower electrode 7 formed on the base substrate 1, a piezoelectric layer 3 formed on the lower electrode 7, and an upper electrode 4 formed on the piezoelectric layer 3. Also, the laminate 10 may have an orientation control layer 6 on the lower electrode 7.

In accordance with the present embodiment, as described above, the piezoelectric layer 3 composed of potassium sodium niobate can be formed at lower temperatures (concretely, with the temperature of the base substrate 1 being preferably between 200° C. and 500° C., and more preferably between 200° C. and 300° C.), compared to an ordinary method for manufacturing a piezoelectric layer. The reason for this is assumed as follows.

FIG. 10 shows a ¹H-NMR analysis result of a solution of water and ethanol added thereto, in which the water was made by flowing water vapor through the oxidizing gas forming section 30, and collecting the discharged water vapor. In contrast, FIG. 11 shows a ¹H-NMR analysis result of a solution of ordinary purified water and ethanol added thereto. It is noted that the water and ethanol were mixed at a mole ratio of 2:1. It is observed from FIG. 10 and FIG. 11 that the peaks of hydroxyl groups of the ordinary purified water and ethanol are separated from each other, but the peaks of hydroxyl groups of the water obtained by passing water vapor through the oxidizing gas forming section 30 and ethanol are superposed with each other.

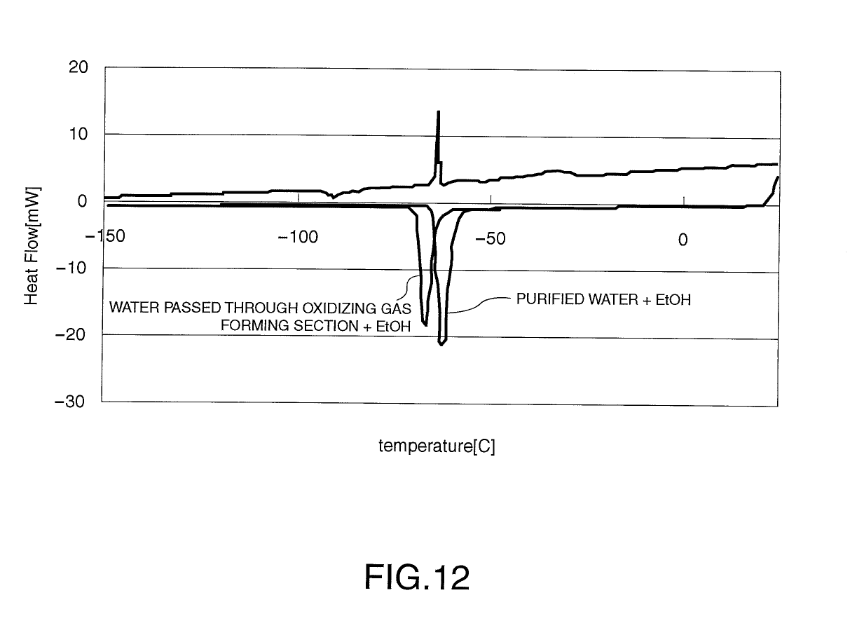

FIG. 12 is a graph that compares results of DSC (Differential Scanning Calorimetry) analysis of a solution of water and ethanol added thereto, in which the water was made by flowing water vapor through the oxidizing gas forming section 30, and collecting the discharged water vapor, and a solution of ordinary purified water and ethanol added thereto. In the graph showing the DSC measurement results, two peaks of each of the solutions indicate coagulation (water to ice) and fusion (ice to water). By obtaining an integration from the starting point to the end point of each of the peaks (in other words, obtaining a peak area), the enthalpy, the energy that requires for each of the phenomena, can be obtained. The obtained enthalpy values are shown in Table 1. It is observed from comparison of the peaks associated with coagulation and fusion that the mixed solution of water obtained by passing water vapor through the oxidizing gas forming section 30 and ethanol has smaller coagulation enthalpy and fusion enthalpy than those of the mixed solution of ordinary purified water and ethanol.

TABLE 1

| | Fusion | Coagulation |
|---|---|---|
| | Enthalpy | Enthalpy |
| | [J/g] | [J/g] |
| Purified Water + EtOH | 109.1 | −74.9 |
| Water passed through | 86.5 | −63.1 |
| Oxidizing Gas Forming | | |
| Section + EtOH | | |

It is believed that the result indicates that water molecules of the water obtained by passing through the oxidizing gas forming section 30 are in a non-clustered state (in which all or most of the water molecules are not in a cluster state, but in a disjoined state). In other words, it is believed that water vapor (H₂O) and oxygen gas (O₂) introduced in the oxidizing gas forming section gain higher energy through repeating collisions and diffusions, and become an active species with strong oxidizability. In accordance with the present embodiment, active oxidizing gas with strong oxidizability can be supplied in the oxidation furnace 20, and therefore it is assumed that the piezoelectric layer 3 can be formed at low temperatures.

### 2. Experimental Example

### 2.1. Embodiment Example 1

Potassium ethoxide, sodium ethoxide and niobium ethoxide were mixed at a mole ratio of K:Na:Nb=0.5:0.6:1.0, and the mixed solution was refluxed in butyl celsolve, thereby preparing a triple alkoxide solution. Further, diethanolamine was added to the solution as a stabilizing agent of the solution. In this manner, a precursor solution was prepared. It is noted that acetic acid may be used instead of diethanolamine. The precursor solution was coated by a spin coat method on a STO (SrTiO₃) single crystal substrate in a (100) orientation (base substrate 1), thereby forming a material layer 2, whereby a laminate 10 was obtained. Next, the laminate 10 was mounted on a hot plate, thereby drying and further temporarily sintering the material layer 2. Then, the laminate 10 was mounted on the base substrate mounting section 12 in the oxidation furnace 20 of the piezoelectric layer manufacturing apparatus 100 shown in FIG. 2, oxidized by water vapor at 150° C., and treated by rapid thermal annealing at 500° C. to crystallize the material layer 2, whereby a piezoelectric layer 3 having a film thickness of about 0.5 μm was formed.

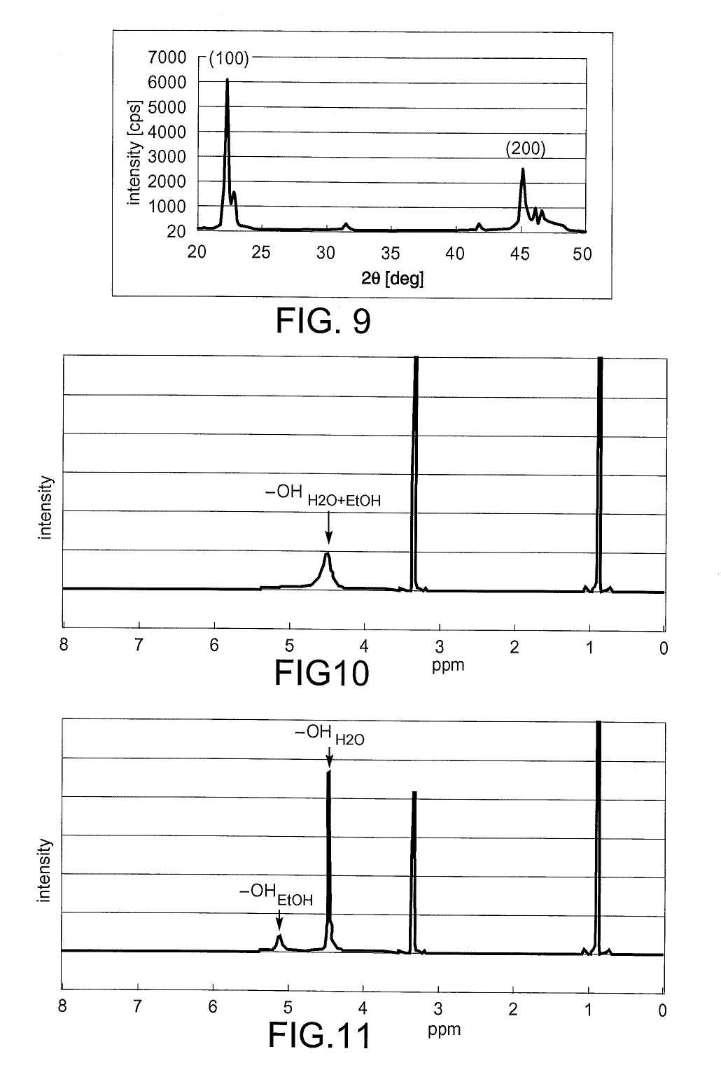

The piezoelectric layer 3 composed of potassium sodium niobate thus obtained was examined by X-ray analysis (θ-2θ), whereby the result shown in FIG. 9 was obtained. It was confirmed from FIG. 9 that, in the embodiment example, a potassium sodium niobate layer in a (100) single orientation without heterogeneous phases was obtained.

The invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A method for manufacturing a piezoelectric layer, the method comprising the steps of:
forming a material layer of a piezoelectric layer composed of potassium sodium niobate above a base substrate;
introducing material gas containing water vapor and oxygen gas in an oxidizing gas forming section; and
heating the material gas in the oxidizing gas forming section and supplying the material gas in an oxidation furnace to thereby oxidize the material layer.

2. A method for manufacturing a piezoelectric layer according to claim 1, wherein the step of forming the material layer includes coating a solution containing a raw material solution for forming the piezoelectric layer, and applying a heat treatment to the solution coated.

3. A method for manufacturing a piezoelectric layer according to claim 1, wherein the oxidizing gas forming section at least includes a first gas chamber section, a plurality of conduction pipes connected to the first gas chamber section, a second gas chamber section connected to the plurality of conduction pipes, and a supply section connected to the second gas chamber for supplying the oxidizing gas to the oxidation furnace.

4. A method for manufacturing a piezoelectric layer according to claim 3, wherein the step of supplying the oxidizing gas from the oxidizing gas forming section to the oxidation furnace includes a first step of supplying the oxidizing gas to the first gas chamber section, and a second step of supplying the oxidizing gas through the plurality of conduction pipes to the second gas chamber section.

5. A method for manufacturing a piezoelectric layer according to claim 1, wherein the temperature of the base substrate in the step of oxidizing the material layer is between 200° C. and 500° C.

6. A method for manufacturing a piezoelectric layer according to claim 1, wherein the temperature of the base substrate in the step of oxidizing the material layer is between 200° C. and 300° C.

7. A method for manufacturing a piezoelectric layer according to claim 1, wherein water molecules of the oxidizing gas that is supplied to the oxidation furnace are in a non-cluster state.
